(19) United States
(12) Patent Application Publication
(10) Pub. No.: US 2026/0005163 A1
(43) Pub. Date: Jan. 1, 2026

(54) GLASS CORE SUBSTRATES WITH COUPLED INDUCTOR STRUCTURES

(71) Applicant: Intel Corporation, Santa Clara, CA (US)

(72) Inventors: Brandon C. Marin, Gilbert, AZ (US); Jaeil Baek, Chandler, AZ (US); Beomseok Choi, Chandler, AZ (US); Kaladhar Radhakrishnan, Chandler, AZ (US); Srinivas Pietambaram, Chandler, AZ (US)

(73) Assignee: Intel Corporation, Santa Clara, CA (US)

(21) Appl. No.: 18/757,211

(22) Filed: Jun. 27, 2024

(51) Int. Cl. H01L 23/64; H01L 23/00; H01L 23/14; H01L 23/15; H01L 23/538; H01L 25/16

(52) U.S. Cl. CPC H01L 23/645; H01L 23/15; H01L 23/5383; H01L 25/162; H10D 1/20; H01L 23/145; H01L 24/08; H01L 24/16; H01L 2224/08145; H01L 2224/16227

(57) ABSTRACT

An apparatus comprises a substrate comprising a glass core comprising a first surface, a second surface opposite the first surface, and a region away from peripheral edges of the glass core. The glass core includes a sidewall within the region between the first and second surfaces. A first dielectric material is over the first and second surfaces, along the sidewall, and within the region. The first dielectric material comprises a third surface and a fourth surface opposite the third surface. A magnetic material is between the third and fourth surfaces within the region. First and second plated holes extend through the magnetic material. A second dielectric material is between the first and second plated holes. The first and second plated holes, the magnetic material, and the second dielectric material may form a coupled inductor structure.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package can also communicatively connect the IC chip to other packaged IC chips and/or a scaled host component, such as a package substrate, or a printed circuit board. Multiple IC chips can be co-assembled, for example, into a multi-die package (MCP).

In traditional methods, IC chips or dies may be placed side by side on a substrate. Each IC chip is electrically coupled to the substrate by contacts and receives power from the substrate via some of the contacts. To obtain tighter integration than is possible using traditional methods, IC chips may be stacked on top of each other using three-dimensional (3D) packaging techniques. When IC chips are stacked on top of each other, the amount of power that needs to be delivered within a given area increases in comparison to where IC chips are placed side by side. For example, stacking two similar IC dies may double the current density and resistance for the substrate area under the bottom IC die in comparison to a configuration in which the IC dies are placed side by side on the substrate.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIG. 1 illustrates an example integrated circuit package constructed in accordance with some embodiments;

FIGS. 2A, 2B, 2C and 2D are isometric and cross-sectional side views of a coupled inductor structure according to some embodiments;

FIGS. 3A, 3B, 3C and 3D are isometric and cross-sectional side views of another coupled inductor structure according to some embodiments;

FIGS. 4A, 4B, 4C and 4D are plan and cross-sectional views of an example region of a package substrate comprising a glass core with integrated coupled inductor structures according to some embodiments;

FIGS. 5A, 5B, 5C and 5D are plan and cross-sectional views of another example region of a package substrate comprising a glass core with integrated coupled inductor structures according to some embodiments;

FIGS. 6A-6L illustrate stages of manufacturing a glass core with integrated coupled inductor structures that may be provided within a package substrate according to some embodiments;

FIG. 7 illustrates a mobile computing platform and a data server machine employing one or more apparatus comprising an optical feature at an end face of an optical fiber coupled with an optical feature on a surface of a PIC die, in accordance with some embodiments; and

FIG. 8 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

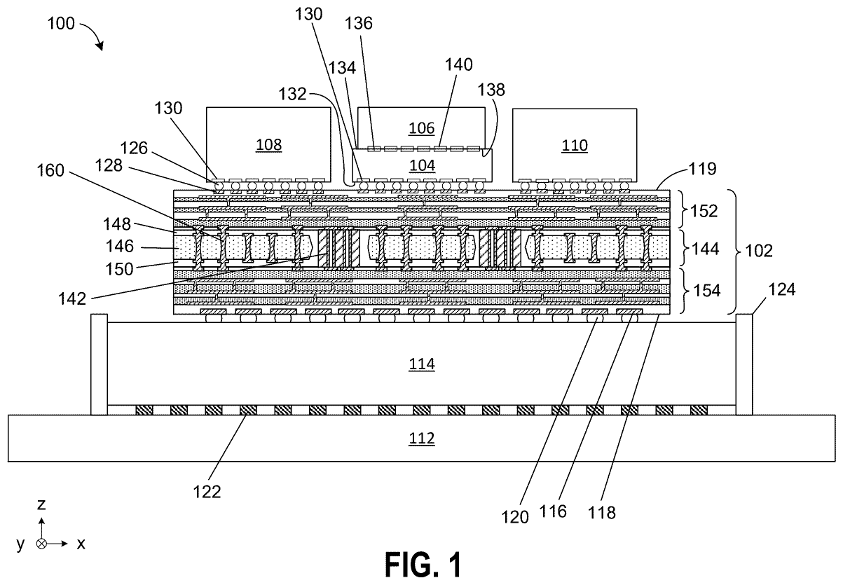

FIG. 1 illustrates an example integrated circuit (IC) package in accordance with some embodiments. The IC package 100 includes a package substrate 102. In this example, the IC package 100 includes four semiconductor dies. In other examples, the IC package 100 may have more or fewer dies. The semiconductor dies may be referred to as IC dies, chips, or chiplets. The semiconductor dies may include circuitry to perform any desired function, e.g., logic, data processing, data communication, or memory. In this example, the IC package 100 includes IC dies 104, 108, and 110 mounted on the package substrate 102. IC dies 106 is mounted to IC die 104. The IC dies and the package substrate 102 may be enclosed in a mold material (not shown). In addition to providing structural support for the IC dies, electrical signals are routed between the IC dies and a circuit board 112 via the package substrate 102.

The IC package 100 is electrically coupled to an interposer 114 via an array of contact pads or lands 116 on a surface 118 of the package substrate 102. Surface 118 may be referred to as a bottom surface. The package substrate 102 has a surface 119 that is opposite surface 118, which may be referred to as a top surface. Package substrate 102 may include balls or pins in addition to or instead of contact pads to enable electrical couplings of the package 100 to the interposer 114. The contact pads 116 may be coupled to the interposer 114 by interconnections 120, e.g., solder features. The interposer 114 is electrically coupled to the circuit board 112 by interconnections 122, e.g., solder features. In this example, the interposer 114 is seated in a socket 124 on circuit board 112. In some examples, interposer 114 is omitted and the package substrate 102 is electrically coupled to circuit board 112 via suitable interconnections of any type.

Each of the IC dies 104, 108, and 110 is electrically and mechanically coupled to the substrate 102 by respective arrays of interconnects 126. In the example of FIG. 1, the interconnects 126 may be any of bumps, balls, pins, or pads comprising solder or other metals or alloys. Interconnects 126 couple pads 128 or other conductive features of substrate 102 with pads 130 or other conductive features of IC dies 104, 108, and 110.

In the example of FIG. 1, IC die 104 includes a surface 132 and a surface 134, which is opposite surface 132. Contact pads 128 are at surface 132. IC die 104 also has metal features 136, e.g., contacts or pads, at surface 134. Metal features 136 may be flush with surface 134 and separated by a dielectric material. Further, in the example of FIG. 1, IC die 106 includes a surface 138 that faces surface 134. The surface 138 has metal features 140, e.g., contacts or pads, that are separated by dielectric material. Metal features 140 may be flush with surface 138.

In a technique referred to as a hybrid bonding, two IC dies may be electrically and mechanically coupled to one another. In this technique, surface metal features embedded within an insulator of one IC die are directly fused to surface metal features embedded within an insulator of another die. The hybrid bonded interface between the dies may include both metallurgically interdiffused metals and chemically bonded insulators. In hybrid bonding, dielectric portions, e.g., oxide, are bonded together with Van der Waals forces, while metal to metal bonds are formed by high temperature processing.

In some embodiments, IC die 104 and IC die 106 are electrically and mechanically coupled to one another using a hybrid bonding technique. The interface between surfaces 134 and 138 may be a hybrid bonded interface and the respective metal features 136, 140 on surfaces 134, 138 are hybrid bonded interconnects. In other examples, IC dies 104 and 106 may be electrically and mechanically coupled to one another using solder bonds or any other suitable technique.

As illustrated in FIG. 1, IC die 106 is stacked on top of IC die 104. IC dies 104 and 106 may have similar power requirements. Stacking one die on top of another increases the power delivery requirement for the area under the two dies. Where the two dies use similar amounts of power, the footprint for the stacked dies can have double the current density and electrical resistance of the footprint for a single die. For this and other reasons, efficient power distribution in an IC package is important.

One approach for achieving efficient power distribution in an IC package is to integrate part or all of voltage regulation circuitry into the package substrate. In various embodiments, inductors used by voltage regulation circuitry are integrated into the package substrate of an IC package. In one example, IC package 100 includes volage regulation circuitry. The voltage regulation circuitry may include transistors and other circuit elements (not shown) in one of the dies, e.g., IC die 108, and one or more capacitors and inductors integrated into package substrate 102. Alternatively, voltage regulation circuitry may include transistors and other circuit elements (not shown) in interposer 114 that operate in conjunction with capacitors and inductors integrated into package substrate 102. In other examples, all components of voltage regulation circuitry may be integrated in the package substrate. In the example of FIG. 1, coupled inductor structures within package substrate 102 that function as inductors are labeled with reference number 142. The voltage regulation circuitry operates to deliver power to IC dies 104, 106, 108, and 110. The inductors integrated into a package substrate as described herein are used as components of voltage regulation circuitry, however, in various alternative IC packages, the disclosed inductors may be used in any other type of electrical circuitry.

As illustrated in FIG. 1, package substrate 102 includes a core region 144 that includes a glass core or layer 146 and organic material layers 148, 150. The core region 144 includes through-glass vias 160 (TGVs) that extend through the glass core 146 and coupled inductor structures 142 within openings in the glass core. A package substrate with a glass core is an advantage because glass is more rigid and can accommodate more IC dies than substrates made from organic materials. However, glass is brittle and fabricating coupled inductor structures 142 directly in the glass core is challenging. An advantage of the embodiments described herein is that coupled inductor structures 142 may be fabricated within organic materials using known methods while retaining a glass core within the substrate. Fabricating coupled inductor structures 142 within organic materials using known methods may provide efficiency and manufacturing yield advantages, and simultaneously produce substrates having the benefits of a glass core.

Glass core 146 comprises a glass that is advantageously predominantly silicon and oxygen. In some embodiments, the glass comprises at least 23 percent silicon and at least 26 percent oxygen, by weight (i.e., wt. %). The glass may further include one or more additives, such as, Aluminum, Boron, Magnesium, Calcium, Barium, Tin, Sodium, Potassium, Strontium, Phosphorus, Zirconium, Lithium, Titanium, or Zinc. In some embodiments where the glass comprises at least 23 wt. % Si and at least 26 wt. % O, the glass further comprises at least 5 wt. % Al. Additives within the glass may form suboxides (A2O) monoxides (AO), binary oxides (AO2), ternary oxides (ABO3), and mixtures thereof. For example, the glass may comprise AlOx (e.g., Al₂O₃), BOx (e.g., B2O3), MgOx (e.g., MgO), CaOx (e.g., CaO), SrOx (e.g., SrO), BaOx (e.g., BaO), SnOx (e.g., Sn02), NaOx (e.g., Na₂O), KOx (e.g., K₂O), POx (e.g., P2O3), ZrOx (e.g., ZrO2), LiOx (e.g., Li₂O), TiOx (e.g., TiO2), or ZnOx (e.g., ZnO2). Depending on chemical composition, the glass may therefore be referred to as silica, fused silica, aluminosilicate, borosilicate, or alumino-borosilicate, for example.

Glass core 146 comprises a glass that is advantageously a bulk material of substantially homogeneous composition in contrast to a composite material that may merely comprise glass fillers and/or fibers. Although the glass is substantially amorphous in some embodiments, the glass may also have other morphology or microstructure, such as polycrystalline (e.g., nanocrystalline).

In addition to core region 144, package substrate 102 includes buildup layers on either or both sides of glass core 146. In the example of FIG. 1, a buildup layer 152 over core region 144 and buildup layer 154 under core region 144 are illustrated. Buildup layers 152, 154 may include an organic dielectric material, such as Ajinomoto® Build-up Film (ABF), polyimide, or other suitable material. Buildup layers 152, 154 may include metallization. In some embodiments, buildup layers 152, 154 are only a single layer of organic dielectric material and conductive traces (or vias), In other embodiments, buildup layers 152, 154 include multiple layers of conductive traces (and/or vias) and organic dielectric material. An outer layer (e.g., the top-most or bottom-most layer) of buildup layers 152, 154 may be formed from an organic dielectric material that is different from the inner layers. For example, the outer layer may be solder resist.

It is an advantage to integrate voltage regulation (VR) circuitry into an IC package. This often means that one or more inductors need to be embedded into a component, e.g., the package substrate, of the IC package for use with the integrated VR circuitry. One approach is to use air core inductor structures for the integrated VR circuitry. Another prior approach is to use an inductor structure that is surrounded by magnetic material, sometimes referred to as a coaxial metal inductor loop. In the coaxial metal inductor loop approach, a plated through-hole (PTH) is formed in a magnetic material. The PTH includes a metal liner and a dielectric core. A drawback of the coaxial metal inductor loop approach is the relatively large physical space required for the structure.

The embodiments described herein are directed to an inductor structure having two or more PTHs disposed in a single body of magnetic material. The example inductor structures may be referred to as coupled coaxial metal inductor loop structures. In these structures, the two or more PTHs are magnetically coupled and the entire structure may behave as a single inductor. Each PTH includes a metal liner and a dielectric core. In some examples, which may be referred to for convenience as “fully coupled,” a zone or slot between two adjacent PTHs is filled with air or a solid non-magnetic dielectric material. In other examples, the body of magnetic material not only surrounds two adjacent PTHs, it also occupies the space between the PTHs, i.e., a zone or slot area. One advantage of coupled coaxial metal inductor loop structures is that they require less physical space than the coaxial metal inductor loop structures. Another advantage of coupled coaxial metal inductor loop structures is that may provide superior electrical properties, e.g., higher inductance, as compared with air core and coaxial metal inductor loop inductor structures.

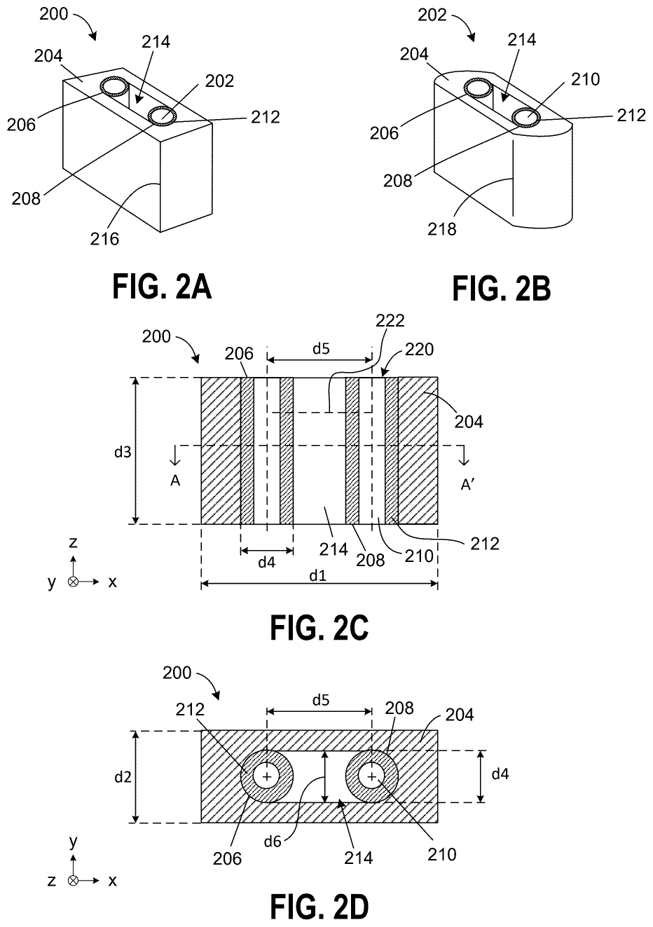

FIGS. 2A and 2B are isometric views of coupled inductor structures that can be provided within a glass core substrate according to some embodiments. FIG. 2C is a cross-sectional side view of the coupled inductor structure of FIG. 2A. FIG. 2D is a cross-sectional side view of the coupled inductor structure of FIG. 2C taken along the line A-A′. In some embodiments, the coupled inductor structures depicted in FIGS. 2A-2D correspond to the coupled inductor structures 142 in FIG. 1.

FIG. 2A illustrates a first example coupled inductor structure 200 and FIG. 2B illustrates a second example coupled inductor structure 202. Example of the coupled inductor structures 200, 202 each includes a magnetic material 204. Coupled inductor structures 200, 202 include first and second plated holes 206 and 208. The plated holes 206, 208 each include an outer wall 212 of conductive material, e.g., metal, that may be fabricated using a plating process. Within the outer wall 212, the plated holes 206, 208 contain an inner core 210 of insulating material, e.g., a dielectric material, that may be fabricated using a deposition process.

Coupled inductor structures 200, 202 are similar, but differ with respect to outer corners of the magnetic material 204. Corners 216 of coupled inductor structure 200 are square while corners 218 of coupled inductor structure 202 are rounded. The geometric shape of the corners of the coupled inductor structures described herein is not critical and may take any suitable shape. In the example illustrated in FIGS. 2A and 2B, plated holes 206, 208, outer wall 212, and inner core 210 are cylindrical. However, the cylindrical shape is not critical. In other examples, outer wall 212, and inner core 210 may be fabricated in any suitable shape, e.g., with flat sides such as a cuboid or pentagonal prism. The metal portion, i.e., outer wall 212, of plated holes 206, 208 may surround the insulating portion, i.e., inner core 210 in the x- and y-directions. In addition, outer wall 212 may contact magnetic material 204. Further, outer wall 212 may be between magnetic material 204 and inner core 210.

In various embodiments, the conductive material of outer wall 212 may be copper or another suitable metal. The insulating or dielectric material of inner core 210 may be an organic material, such as epoxy. The magnetic material 204 may be any suitable material with magnetic properties. In some examples, magnetic material 204 is a dielectric material or an organic material comprising a ferromagnetic material, a ferrimagnetic material, or a Heusler alloy. In an embodiment, the magnetic material 204 comprises a mixture of an organic material and a ferromagnetic material, a ferrimagnetic material, or a Heusler alloy. In some embodiments, magnetic material 204 is Ajinomoto® Magnetic Paste (AMP). In some examples, magnetic material 204 comprises iron, an alloy containing iron, ferrite, or a substance containing ferromagnetic particles. In some embodiments, magnetic material 204 may be formed of a dielectric with magnetic particles or flakes. For example, magnetic material 204 may comprise a non-conductive organic or inorganic material comprising magnetic particles or flakes, such as iron, nickel, cobalt, and their alloys, where the magnetic particles have a diameter between 5 nanometers and 50 microns, and are distributed throughout the dielectric material.

In cross-section, coupled inductor structures 200, 202 may have a generally rectangular shape. As illustrated in FIGS. 2C and 2D, coupled inductor structure 200 has a length d1 in the x dimension, a width d2 in the y dimension, and a height d3 in the z dimension. In various embodiments, length d1 may be approximately 750 μm, but may be larger or smaller. In various embodiments, width d2 may be approximately 450 μm, but may be larger or smaller. In various embodiments, height d3 may be any height in a range of 300 μm to 2.0 mm.

In the example of FIGS. 2C and 2D, a distance d4 across plated holes 206, 208, e.g., a diameter, may be approximately 150 μm, but may be any another distance in a range of 50 μm to 400 μm. In one example, a thickness of outer wall 212 may be approximately 33 percent of distance d4, while inner core 210 may have a diameter of approximately 67 percent of distance d4. Other dimensions for the thickness of outer wall 212 and the diameter inner core 210 are possible. A pitch for the plated holes is given by an x-direction distance d5 between a center of plated hole 206 and a center of plated hole 208. The pitch of or distance d5 between plated holes 206, 208 may be any distance less than approximately 500 μm. In some examples, distance d5 is within a range of 200 μm to 400 μm. In one example, the respective centers of plated holes 206, 208 are spaced apart by a distance d5, and the distance d5 is less than 2.5 times the diameter d4 of plated hole 206 or plated hole 208. The thickness (in an x-y plane) of magnetic material 204 between outer wall 212 and the peripheral surface of plated holes 206, 208 may be approximately 150 μm. In some examples, the thickness of magnetic material 204 may be a distance within a range of 50 μm to 500 μm. The thickness of magnetic material 204 may be uniform or may vary.

Coupled inductor structures 200, 202 each include a zone 214 between plated hole 206 and plated hole 208. Zone 214 may alternatively be referred to as a slot and may extend vertically (in the z-direction) for the full height d3. However, in some examples, zone 214 may extend vertically less than the full height d3. The area between plated hole 206 and plated hole 208, i.e., zone 214, may have a length up to the length d5 between respective centers of the plated holes. In some examples, the length of the area between plated hole 206 and plated hole 208 may extend between the shortest distance between the peripheries of plated hole 206 and plated hole 208. Zone 214 has a width d6 (in the y-direction). In various embodiments, the length d5 of zone 214 is in a range of approximately 50 μm to 750 μm. In various embodiments, the width d6 of zone 214 is in a range of approximately 20 μm to 200 μm. In one example, a portion of the zone 214 is in a plane parallel to a first surface 220 of the coupled inductor structure 200 (or parallel to a surface of a glass layer in which the coupled inductor structure 200 is embedded). The plane may extend in the y- and x-directions. A width d6 of the zone lies in the plane and is perpendicular to an axis 222 between respective centers of the first and second plated holes, 206, 208. The width d6 is less than or equal to a diameter d4 of either the first or second plated holes, 206, 208.

In the examples shown in FIGS. 2A-2D, zone 214 may be devoid of solid material and occupied with air, e.g., a gas comprising oxygen and nitrogen. In an embodiment, zone 214 is devoid of a magnetic material, e.g., magnetic material 204. In some embodiments, a dielectric material is disposed within zone 214, e.g., a solid organic material, such as mold or epoxy, or a gas comprising oxygen and nitrogen. In some examples, an organic or dielectric material different from a magnetic material is disposed within zone 214.

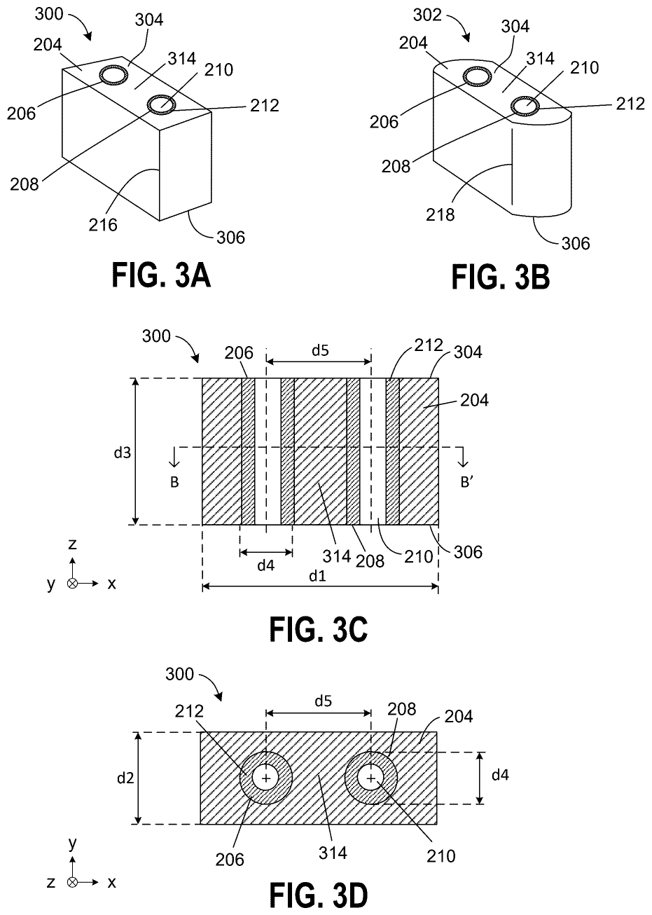

FIGS. 3A and 3B are isometric views of another example of coupled inductor structures that can be provided within a glass core substrate according to some embodiments. FIG. 3C is a cross-sectional side view of the coupled inductor structure of FIG. 3A. FIG. 3D is a cross-sectional side view of the coupled inductor structure of FIG. 3C taken along the line B-B′. In some embodiments, the coupled inductor structures depicted in FIGS. 3A-3D correspond to the coupled inductor structures 142 in FIG. 1.

The coupled inductor structures 300, 302 shown in FIGS. 3A-3D are similar to the coupled inductor structures 200, 202 illustrated in FIGS. 2A-2D. Except as noted below, the description of coupled inductor structures 200, 202 applies equally to coupled inductor structures 300, 302. Accordingly, the same reference numbers used in the description of coupled inductor structures 200, 202 are used to describe the same or similar features of coupled inductor structures 300, 302.

As illustrated in FIGS. 3A-3D, coupled inductor structures 300, 302 do not have a distinct zone 214 between the plated holes 206, 208. Coupled inductor structures 200, 202 include a slot or zone 214 devoid of a magnetic material between the plated holes 206, 208. In contrast, the magnetic material 204 is disposed in a space 314 corresponding to zone 214 between coupled inductor structures 300, 302. The magnetic material 204 may be a continuous body contacting and surrounding each of the plated holes 206, 208. In some examples, the magnetic material 204 includes a top surface 304 and a bottom surface 306, and the plated holes 206, 208 extend vertically (z-direction) through the magnetic material 204 at least between the top and bottom surfaces 304, 306. In an example, magnetic material 204 is a continuous body that laterally surrounds each individual plated hole 206 and 208. In an embodiment, magnetic material 204 is laterally (in the x-direction) between plated holes 206, 208.

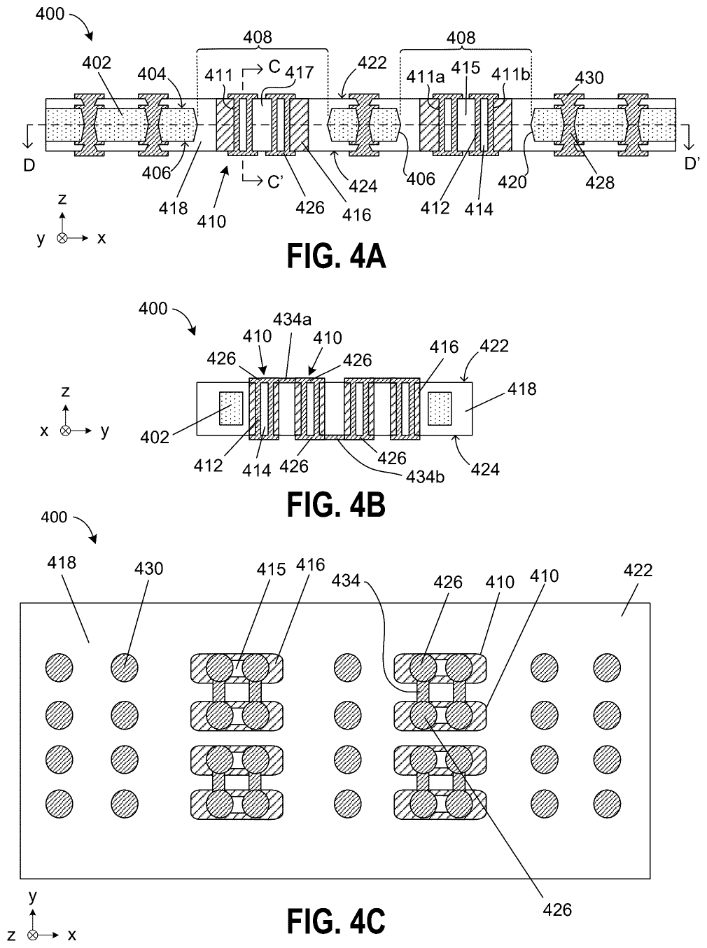

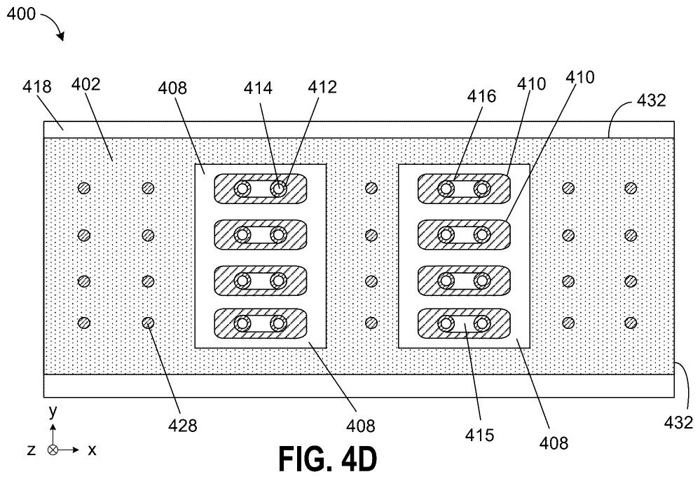

FIG. 4A is cross-sectional side view of an example core region that includes a glass core or layer that can be provided within a package substrate according to some embodiments. FIG. 4B is cross-sectional side view of the core region of FIG. 4A taken along the line C-C′. FIG. 4C is a plan view (top side view) of the core region of FIG. 4A. FIG. 4D is a cross-sectional plan view of the core region of FIG. 4A taken along the line D-D′. In some embodiments, the core region depicted in FIGS. 4A-4D corresponds to the core region 144 illustrated in FIG. 1. The core region 400 shown in FIGS. 4A-4D is similar to core region 144 illustrated in FIG. 1. Except as noted herein, the description of core region 144 applies equally to core region 400. The core region 400 shown in FIGS. 4A-4D may have buildup layers on either or both sides, but buildup layers are not depicted for clarity of illustration.

FIG. 4A is cross-sectional side view of an example core region 400 that can be provided within a package substrate. As illustrated in FIG. 4A, the core region 400 includes a glass core 402 with a top surface 404, a bottom surface 406 opposite the top surface 404, and one or more regions 408, where each region 408 corresponds with an opening through the glass core. One or more coupled inductor structures 410 may be disposed within each region 408.

Coupled inductor structures 410 may be the same as or similar to either coupled inductor structure 200, and the description of coupled inductor structures 200 applies equally to coupled inductor structures 410. Like coupled inductor structures 200, coupled inductor structures 410 include a slot or zone 415 devoid of a magnetic material between adjacent plated holes.

Each coupled inductor structure 410 includes at least two plated holes 411, each plated hole 411 having an outer wall 412 of conductive material and an inner core 414 of dielectric material. As shown in FIG. 4A, 4B, first and second plated holes 411a, 411b may be adjacent one another with a zone 415 between the plated holes 411a, 411b. In the example of FIG. 4A, a non-magnetic dielectric material 417 may be disposed in zone 415. In addition, each plated hole extends vertically (z-direction) through a magnetic material 416. The plated holes 411a, 411b extend at least between the top and bottom surfaces 404, 406 of glass core 402 within a region 408. The magnetic material 416 may be a continuous body laterally surrounding the plated holes 411 within a region 408. In some examples, the magnetic material 416 may be between the top and bottom surfaces 404, 406 of glass core 402 within the region 408.

The core region 400 also includes an organic material 418 within each region 408 that laterally surrounds the magnetic material 416. In various embodiments, organic material 418 is a dielectric material, such as mold or epoxy. As illustrated in FIG. 4A, the organic material 418 is over the top and bottom surfaces 404, 406 of glass core 402, and along at least one sidewall 420 of an opening through the glass core corresponding with a region 408. The organic material 418 includes an upper surface 422 and a lower surface 424 opposite the upper surface 422.

Each plated hole 411 may extend vertically through the magnetic material 416. In some examples, the magnetic material 416 is between upper and lower surfaces 422, 424 of organic material 418 within the region 408, as shown in FIG. 4A. In some embodiments, plated holes 411 may extend into buildup layers 152, 154 above or below organic material 418. A plated hole 411 may have a conductive cap 426 (also referred to as a contact or metal feature) on either or both of upper and lower ends of the plated hole. In some examples, conductive cap 426 is on or at upper surface 422 and lower surface 424. In other examples, conductive cap 426 is on or at top surface 404 or bottom surface 406. If present, conductive cap 426 contacts the outer wall 412 of conductive material. The conductive caps may be metal and serve as contacts to electrically couple a coupled inductor structure 410 with other electrically conductive features, such as laterally metallization in a layer, a vertical conductive via, another coupled inductor structure 410, or any suitable electrical component. For example, conductive cap 426 and one or more electrically conductive features 434 may couple a coupled inductor structure 410 with circuit elements of an integrated VR. As illustrated in FIG. 4A, glass core 402 may include one or more through-glass vias 428 (TGVs) that extend through the glass core 402. TGVs may have caps, contacts, or metal features 430 on either or both of upper and lower ends of the TGV.

As illustrated in FIG. 4B, an electrically conductive feature 434a on or at upper surface 422 of organic material 418 contacts and electrically couples conductive caps 426 of two coupled inductor structures 410. Also shown in FIG. 4B, an electrically conductive feature 434b on or at lower surface 424 of organic material 418 contacts and electrically couples conductive caps 426 of two coupled inductor structures 410. FIG. C is a plan view illustrating multiple electrically conductive features 434 on or at surface 422 of organic material 418 contacting and electrically coupling conductive caps 426 of two coupled inductor structures. FIG. 4D is a cross-sectional plan view of the core region of FIG. 4A taken along the line D-D′ that illustrates multiple regions 408 away from peripheral edges 432 of the glass layer 402. Within each region 408, multiple coupled inductor structures 410 are shown in cross section with organic material 418 laterally surrounding the coupled inductor structures.

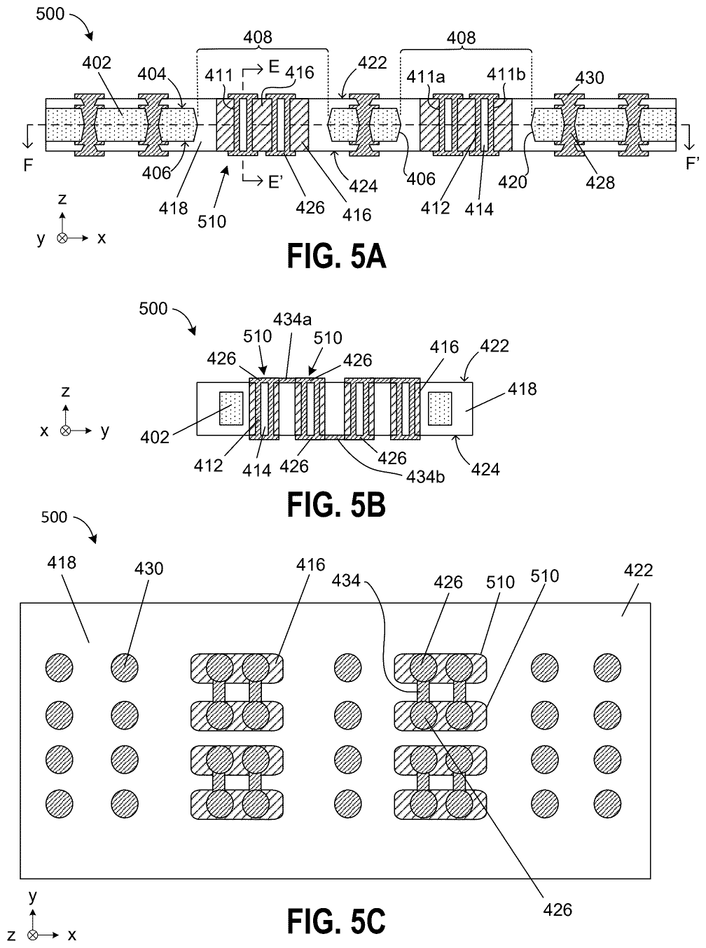

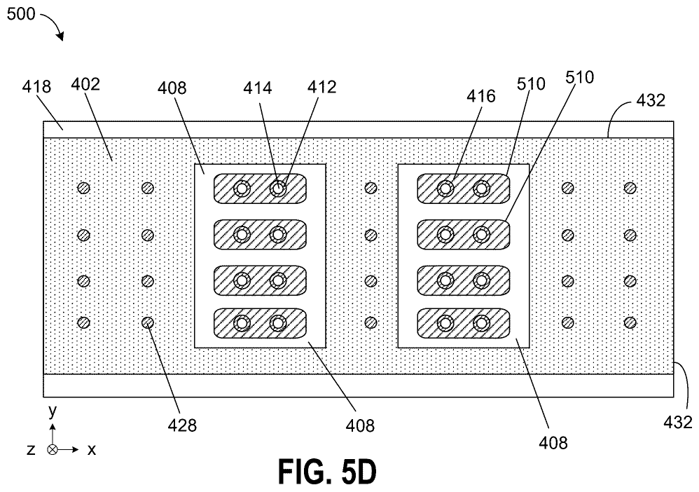

FIG. 5A is cross-sectional side view of another example core region that includes a glass core or layer that can be provided within a package substrate according to some embodiments. FIG. 5B is cross-sectional side view of the core region of FIG. 5A taken along the line E-E′. FIG. 5C is a plan view (top side view) of the core region of FIG. 5A. FIG. 5D is a cross-sectional plan view of the core region of FIG. 5A taken along the line F-F′. In some embodiments, the core region depicted in FIGS. 5A-5D corresponds to the core region 144 illustrated in FIG. 1. The core region 500 shown in FIGS. 5A-5D is similar to core region 144 illustrated in FIG. 1. Except as noted herein, the description of core region 144 applies equally to core region 500. The core region 500 shown in FIGS. 5A-5D may have buildup layers on either or both sides, but buildup layers are not depicted for clarity of illustration.

The core region shown in FIGS. 5A-5D is similar to the core region 400 illustrated in FIGS. 4A-4D. Except as noted below, the description of core region 400 applies equally to core region 500. Accordingly, the same reference numbers used in the description of core region 400 are used to describe the same or similar features of core region 500.

As illustrated in FIGS. 5A-5D, the coupled inductor structures 510 integrated into core region 500 do not have a distinct zone 415 between adjacent plated holes 411. Rather, magnetic material 416 is disposed in a space corresponding to zone 415 between plated holes 411 in coupled inductor structures 510. The coupled inductor structures 510 depicted in FIGS. 5A-5D may be the same as the coupled inductor structures 300, 302 illustrated in FIGS. 3A-3D. The description of coupled inductor structures 300 applies equally to coupled inductor structures 510.

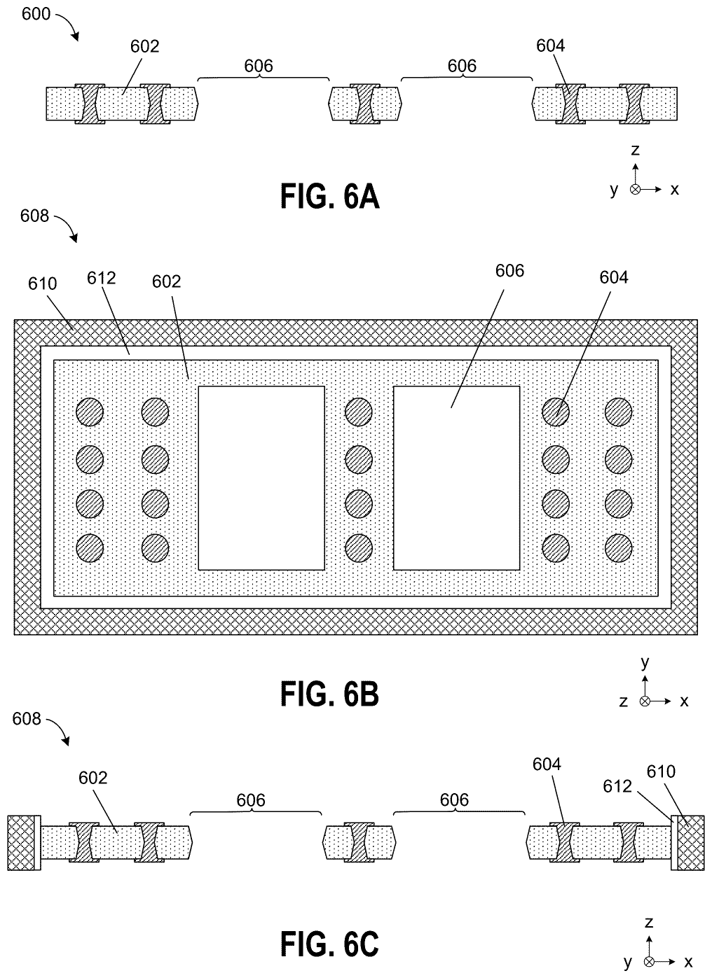

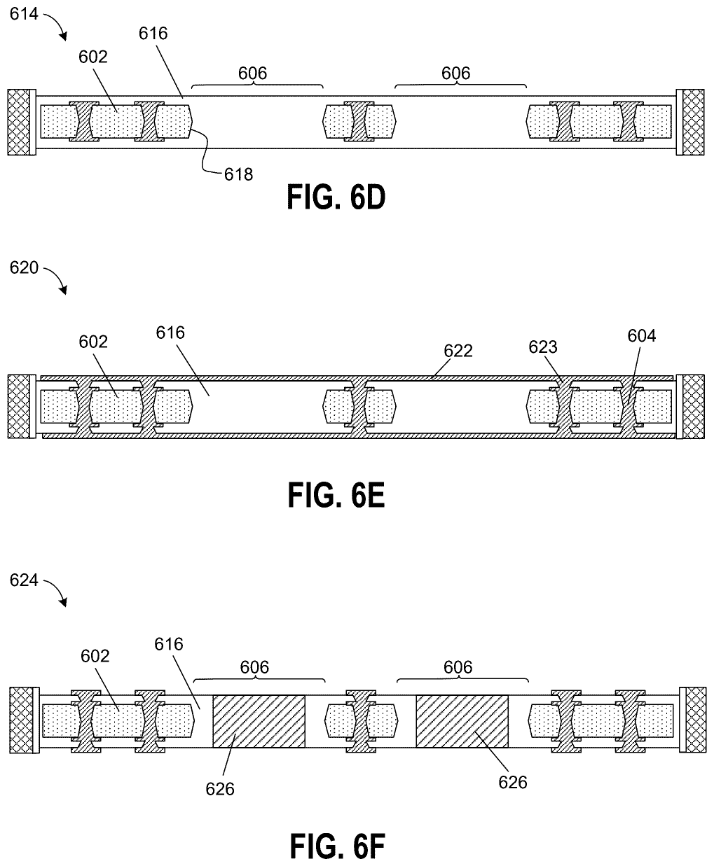

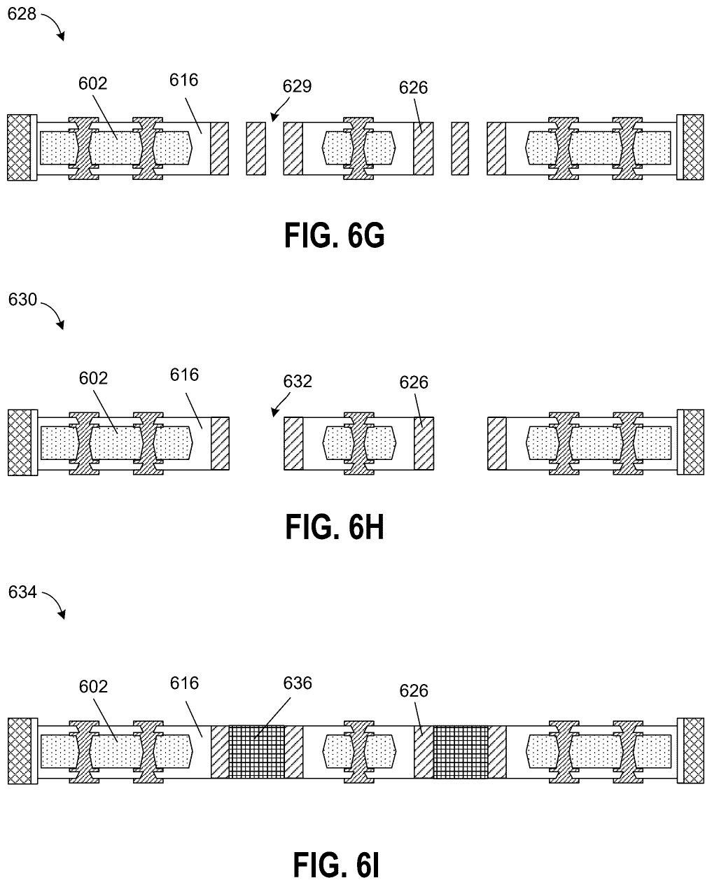

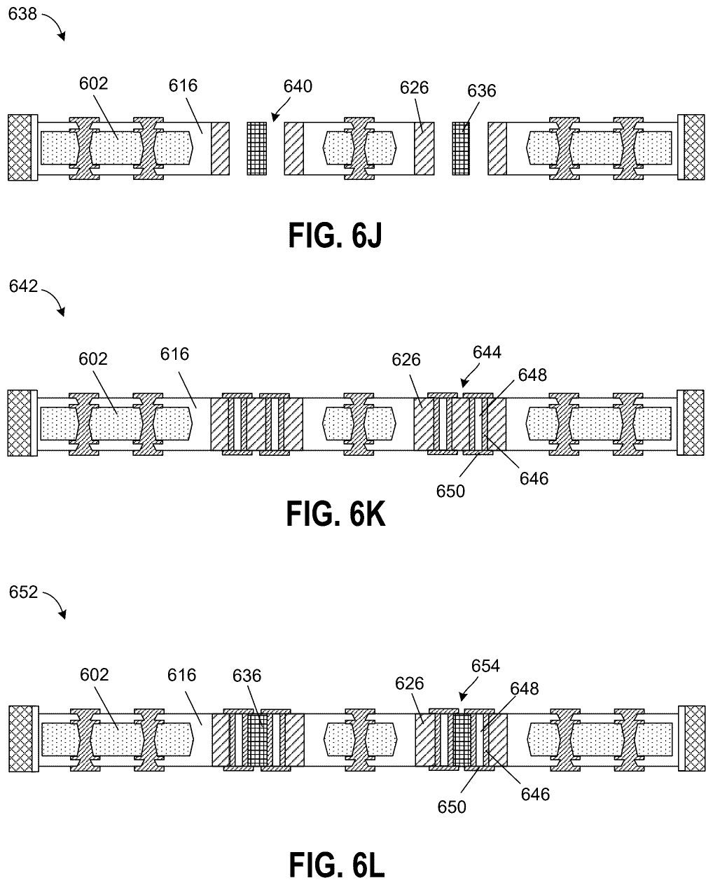

FIGS. 6A-6L generally illustrates stages of a process for fabricating a core region, e.g. region 144, that includes a glass core or layer comprising coupled inductor structures that can be provided within a package substrate according to various embodiments. In particular, FIGS. 6A-6L illustrate steps of a process for making core region 400 that includes a glass core 402 with coupled inductor structures having a zone 415 between adjacent plated holes 411 filled with a non-magnetic dielectric 417, e.g., coupled inductor structures 200. FIGS. 6A-6L also illustrate steps of a process for making core region 500 that includes a glass core 402 with coupled inductor structures having adjacent plated holes 411 completely surrounded by a dielectric material 416, e.g., coupled inductor structures 300.

At a stage of manufacturing 600, a glass panel or core 602 is received as a starting workpiece, as illustrated in FIG. 6A. The glass panel or core 602 may be of any suitable size, e.g., a full panel, a quarter panel, or the size of an individual package substrate. In the stages that follow, for convenience of illustration, it is assumed the glass size corresponds to a portion of an individual package substrate. Stage 600 is after holes or openings through the glass 602 have been formed. Some openings are for TGVs and stage 600 is also after TGVs have been fabricated in these openings. Other openings are for fabrication integration of coupled core inductor structures in subsequent stages.

At a stage of manufacturing 600, TGVs 604 are shown as fully fabricated. However, in some examples, TGVs may be fabricated at a later stage of manufacturing. The openings reserved for coupled core inductor structures are in regions 606. Holes may be formed in the glass core during a casting process or may be formed after casting, e.g., by imprinting, sand blasting, laser drilling, etching, or laser-assisted etching. Electrically conductive material may be deposited in the holes reserved for TGVs by any suitable process, such as, for example, screen printing techniques, plating techniques (electroplating or electroless plating), chemical vapor deposition (CVD), and physical vapor deposition (PVD).

FIG. 6B and FIG. 6C illustrate a stage of manufacturing 608 after glass core 602 has been encapsulated in a frame. FIG. 6B is a plan view of glass core 608 and FIG. 6C is a cross-sectional side view of glass core 608. In the example depicted in FIG. 6B and FIG. 6C, the glass core 602 is held in a frame 610 of copper clad laminate (CCL) or other organic material. A mold or epoxy 612 may be used to secure the glass core 602 to the frame 610. The frame serves to protect the glass from cracking or breaking during processing and handling.

FIG. 6D illustrates a stage of manufacturing 614 after a mold material 616 is formed on a top surface, and a bottom surface 406 opposite the top surface of glass core 608, and within openings through the glass in regions 606. As can be seen in FIG. 6D, mold material 616 is formed along sidewalls 618. Mold in liquid form may be dispensed onto surfaces and subsequently planarized using a grinding process after the mold hardens.

FIG. 6E illustrates a stage of manufacturing 620 after holes have been formed through mold material 616 over the TGVs. Stage 620 is also after metal 622 has been deposited on the top and bottom surface and within the holes to form through-mold vias 623 contacting the TGVs. Holes may be formed using any suitable drilling process.

FIG. 6F illustrates a stage 624 of manufacturing after openings have been formed in mold material 616 within regions 606, and the openings have been filled with a magnetic material 626. Stage 624 is also after the mold material 616 has been planarized, such as by a grinding operation. In addition, stage 624 is after the metal 622 on the surfaces has been patterned. Metal patterning may be accomplished using any suitable technique, such as a mask and etch process.

In one alternative, FIG. 6G illustrates a stage 628 of manufacturing after holes 629 have been formed in magnetic material 626 within regions 606. In in later stages, holes 629 will become plated holes of a coupled inductor structure that does not include a zone between adjacent plated holes containing a non-magnetic dielectric material. In another alternative, FIG. 6H illustrates a stage 630 of manufacturing after openings 632 have been formed in magnetic material 626 within regions 606. In in later stages, openings 632 will contain a coupled inductor structure that includes a zone between adjacent plated holes containing a non-magnetic dielectric material.

FIG. 6I illustrates a stage 634 of manufacturing after manufacturing stage 630 illustrated in FIG. 6H. In FIG. 6I, a non-magnetic dielectric material 636 has been placed within openings 632 and planarized. FIG. 6J illustrates a stage 638 of manufacturing subsequent to stage 634 depicted in FIG. 6I. Stage 638 is after holes 628 have been formed in the non-magnetic dielectric material 636.

FIG. 6K illustrates a stage 642 of manufacturing after stage 628 illustrated in FIG. 6G. In FIG. 6K, coupled inductor structures 644 have been formed in the magnetic material 626. Operations performed to bring the workpiece to stage 642 may include forming plated holes through the magnetic material 626 by plating the holes 628 with a metal to form an outer wall 646, depositing a dielectric material in the holes 628 to form an inner core 648, and forming a conductive cap 650 on an end of the plated holes.

FIG. 6L illustrates a stage 652 of manufacturing after stage 638 illustrated in FIG. 6J. In FIG. 6L, coupled inductor structures 654 have been formed in the magnetic material 626 and non-magnetic dielectric material 636. Operations performed to bring the workpiece to stage 652 may include forming plated holes through the magnetic material 626 and non-magnetic dielectric material 636. Forming plated holes may be accomplished by plating the holes 640 with a metal to form an outer wall 646, depositing a dielectric material in the holes 628 to form an inner core 648, and forming a conductive cap 650 on an end of the plated holes. In an alternative, the non-magnetic dielectric material 636 between the adjacent plated holes may be removed, such as be mechanical drilling process, or be an etching process, and replaced with air or other gas.

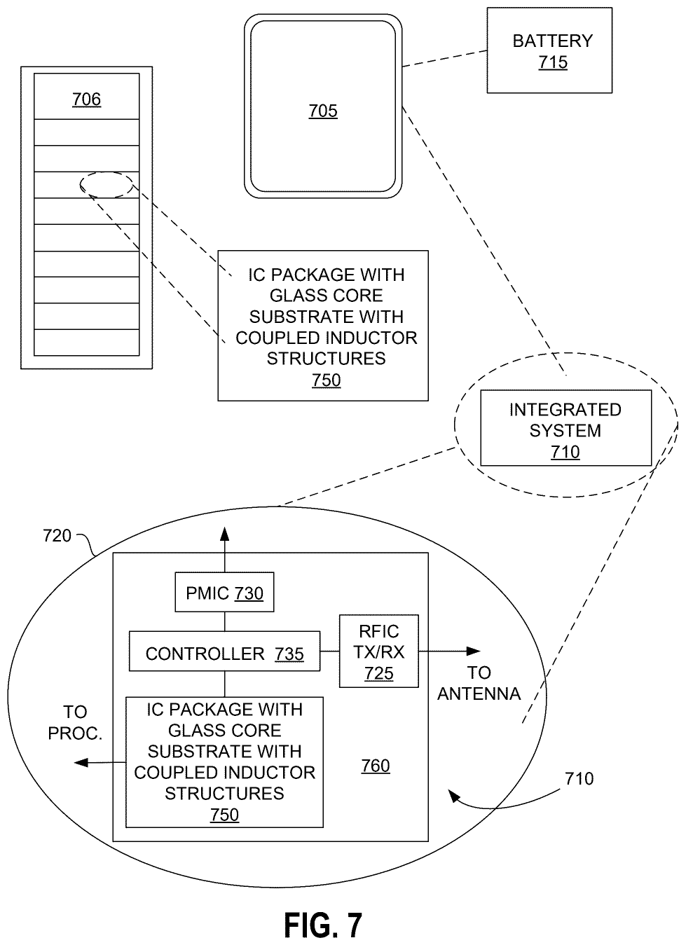

FIG. 7 illustrates a mobile computing platform and a data server machine employing one or more apparatus comprising an IC package 750 with a glass core substrate with coupled inductor structures integrated into the substrate, for example as described elsewhere herein. Server machine 706 may be any commercial server, for example including any number of high-performance computing platforms disposed within a rack and networked together for electronic data processing. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715.

Whether disposed within the integrated system 710 illustrated in the expanded view 720, or as a stand-alone package within the server machine 706, the IC package 750 with a glass core substrate with coupled inductor structures integrated into the substrate, as described elsewhere herein. IC package 750 may be further coupled to a host substrate 760, along with, one or more of a power management integrated circuit (PMIC) 730, RF (wireless) integrated circuit (RFIC) 725 including a wideband RF (wireless) transmitter and/or receiver (TX/RX) (e.g., including a digital baseband and an analog front-end module further comprises a power amplifier on a transmit path and a low noise amplifier on a receive path), and a controller 735. PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

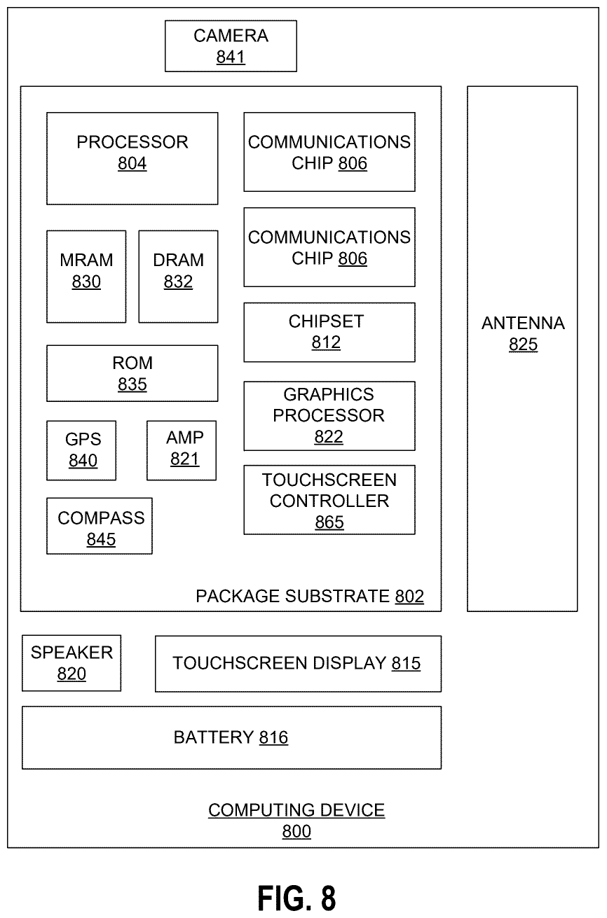

FIG. 8 is a functional block diagram of an electronic computing device 800, in accordance with an embodiment of the present invention. The computing device may be found inside mobile computing platform 705 or server machine 706, as described elsewhere herein. Device 800 further includes a package substrate 802 hosting a number of components, such as, but not limited to, a processor 804 (e.g., an applications processor). Processor 804 may be physically and/or electrically coupled to package substrate 802. In general, the term “processor” or “microprocessor” may refer to any device or portion of a device that processes electronic data from registers and/or memory to transform that electronic data into other electronic data that may be further stored in registers and/or memory. In some examples, one or more of the components of computing device 800 includes an IC package 750 with a glass core substrate with coupled inductor structures integrated into the substrate, as described elsewhere herein. In some examples, package substrate 802 comprises glass core substrate with coupled inductor structures integrated into the substrate, as described elsewhere herein.

In various examples, one or more communication chips 806 may also be physically and/or electrically coupled to the package substrate 802. In further implementations, communication chips 806 may be part of processor 804. Depending on its applications, computing device 800 may include other components that may or may not be physically and electrically coupled to package substrate 802. These other components include, but are not limited to, volatile memory (e.g., DRAM 832), non-volatile memory (e.g., ROM 835), flash memory (e.g., NAND or NOR), magnetic memory (MRAM 830), a graphics processor 822, a digital signal processor, a crypto processor, a chipset 812, an antenna 825, touchscreen display 815, touchscreen controller 865, battery 816, audio codec, video codec, power amplifier 821, global positioning system (GPS) device 840, compass 845, accelerometer, gyroscope, speaker 820, camera 841, and mass storage device (such as hard disk drive, solid-state drive (SSD), compact disk (CD), digital versatile disk (DVD), and so forth), or the like.

Communication chips 806 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 806 may implement any of a number of wireless standards or protocols. As discussed, computing device 800 may include a plurality of communication chips 806. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus comprising: a substrate comprising a glass core comprising a first surface, a second surface opposite the first surface, and a region; a magnetic material between the first and second surfaces within the region; a first metal feature, a second metal feature adjacent to the first metal feature, and a dielectric material between the first and second metal features, the first metal feature and second metal feature extending vertically through the magnetic material at least between the first and second surfaces; and an organic material within the region and laterally surrounding the magnetic material.

Example 2: The apparatus of example 1, wherein the magnetic material is a first magnetic material and the dielectric material is a first dielectric material, further comprising: a second magnetic material between the first and second surfaces within the region; a third metal feature, a fourth metal feature adjacent to the third metal feature, and a second dielectric material between the third and fourth metal features, the third metal feature, the fourth metal feature, and the second dielectric material extending vertically through the second magnetic material at least between the first and second surfaces; and an electrically conductive feature on the first surface contacting the first and third metal features.

Example 3: The apparatus of example 1, wherein each of the first and second metal features comprise a metal portion surrounding an insulating material.

Example 4: The apparatus of any of examples 1 through 3, wherein the magnetic material comprises a ferromagnetic material, a ferrimagnetic material, or a Heusler alloy.

Example 5: The apparatus of any of examples 1 through 4, wherein the organic material is a mold material.

Example 6: The apparatus of any of examples 1 through 5, wherein the dielectric material extends vertically between the first and second surfaces.

Example 7: The apparatus of any of examples 1 through 6, wherein the dielectric material is different from the magnetic material.

Example 8: The apparatus of any of examples 1 through 6, wherein the dielectric material comprises the magnetic material.

Example 9: An apparatus comprising: a glass layer comprising a first surface, a second surface opposite the first surface, a region away from peripheral edges of the glass layer, and a sidewall within the region between the first and second surfaces; a first dielectric material over the first and second surfaces, and along the sidewall, the first dielectric material comprising a third surface and a fourth surface opposite the third surface; a magnetic material between the third and fourth surfaces within the region; first and second plated holes through the magnetic material; and a second dielectric material between the first and second plated holes.

Example 10: The apparatus of example 9, wherein respective centers of the first and second plated holes are spaced apart by a distance, and the distance is less than 2.5 times a diameter of the first plated hole.

Example 11: The apparatus of example 9 or 10, wherein the second dielectric material is different from the magnetic material, and the second dielectric material occupies a zone in a plane parallel to the first surface, wherein a width of the zone is perpendicular to an axis between respective centers of the first and second plated holes, and the width is less than or equal to a diameter of the first plated hole.

Example 12: The apparatus of examples 9 or 10, wherein the magnetic material is a first magnetic material, and each of the first and second plated holes comprise a first conductive portion, further comprising: a second magnetic material between the third and fourth surfaces within the region; third and fourth plated holes through the second magnetic material, wherein each of the third and fourth plated holes comprise a second conductive portion; a third dielectric material between the third and fourth plated holes; and an electrically conductive feature on the third surface contacting: the first conductive portion of the first plated through hole, and the second conductive portion of the third plated through hole.

Example 13: The apparatus of example 12, wherein the electrically conductive feature is a first electrically conductive feature, further comprising a second electrically conductive feature contacting: the first conductive portion of the second plated through hole, and the second conductive portion of the fourth plated through hole, wherein the first electrically conductive feature and the second electrically conductive feature are substantially parallel in a plane parallel to the third surface.

Example 14: The apparatus of any of examples 9 through 11, wherein the second dielectric material comprises a gas comprising oxygen and nitrogen.

Example 15: The apparatus of any of examples 9 through 11, or example 14, wherein each of the first and second plated holes comprise conductive portions and insulating material portions, and each conductive portion is between a corresponding insulating material portion and the magnetic material.

Example 16: A system comprising: a first die over a second die, the first die comprising a first surface, the second die comprising a second surface and a third surface opposite the second surface, wherein the first surface is facing the second surface; a substrate under the second die, the substrate comprising: a fourth surface facing the third surface; interconnects between the third surface and the fourth surface to couple the substrate to the second die; a layer comprising solid glass, a first side, and a second side opposite the first side; a dielectric material over the layer and within an opening through the layer; a continuous body of magnetic material within the dielectric material between the first and second sides; and a first plated hole, a second plated hole, and a zone between the first and second plated holes, wherein the first and second plated holes extend through the magnetic material.

Example 17: The system of example 16, wherein the magnetic material is a first magnetic material and the zone is a first zone, further comprising: a continuous body of second magnetic material within the dielectric material between the first and second sides; a third plated hole, a fourth plated hole, and a second zone between the third and fourth plated holes, wherein the third and fourth plated holes extend through the second magnetic material; and an electrically conductive feature extending between the first and third plated holes.

Example 18: The system of example 16 or 17, wherein the interconnects are first interconnects, further comprising second interconnects comprising hybrid bonds between the first surface and the second surface to couple the first die with the second die.

Example 19: The system of example 16, wherein the zone extends vertically between the first and second sides, and comprises a dielectric material different from the magnetic material.

Example 20: The system of example 16, 17, or 18, further comprising a through-glass via extending through the layer and the dielectric material, wherein the layer comprises at least 23 percent silicon and at least 26 percent oxygen, by weight.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus comprising:
a substrate comprising a glass core comprising a first surface, a second surface opposite the first surface, and a region;
a magnetic material between the first and second surfaces within the region;
a first metal feature, a second metal feature adjacent to the first metal feature, and a dielectric material between the first and second metal features, the first metal feature and second metal feature extending vertically through the magnetic material at least between the first and second surfaces; and
an organic material within the region and laterally surrounding the magnetic material.

2. The apparatus of claim 1, wherein the magnetic material is a first magnetic material and the dielectric material is a first dielectric material, further comprising:
a second magnetic material between the first and second surfaces within the region;
a third metal feature, a fourth metal feature adjacent to the third metal feature, and a second dielectric material between the third and fourth metal features, the third metal feature, the fourth metal feature, and the second dielectric material extending vertically through the second magnetic material at least between the first and second surfaces; and
an electrically conductive feature on the first surface contacting the first and third metal features.

3. The apparatus of claim 1, wherein each of the first and second metal features comprise a metal portion surrounding an insulating material.

4. The apparatus of claim 1, wherein the magnetic material comprises a ferromagnetic material, a ferrimagnetic material, or a Heusler alloy.

5. The apparatus of claim 1, wherein the organic material is a mold material.

6. The apparatus of claim 1, wherein the dielectric material extends vertically between the first and second surfaces.

7. The apparatus of claim 6, wherein the dielectric material is different from the magnetic material.

8. The apparatus of claim 6, wherein the dielectric material comprises the magnetic material.

9. An apparatus comprising:
a glass layer comprising a first surface, a second surface opposite the first surface, a region away from peripheral edges of the glass layer, and a sidewall within the region between the first and second surfaces;
a first dielectric material over the first and second surfaces, and along the sidewall, the first dielectric material comprising a third surface and a fourth surface opposite the third surface;
a magnetic material between the third and fourth surfaces within the region;
first and second plated holes through the magnetic material; and
a second dielectric material between the first and second plated holes.

10. The apparatus of claim 9, wherein respective centers of the first and second plated holes are spaced apart by a distance, and the distance is less than 2.5 times a diameter of the first plated hole.

11. The apparatus of claim 9, wherein the second dielectric material is different from the magnetic material, and the second dielectric material occupies a zone in a plane parallel to the first surface, wherein a width of the zone is perpendicular to an axis between respective centers of the first and second plated holes, and the width is less than or equal to a diameter of the first plated hole.

12. The apparatus of claim 9, wherein the magnetic material is a first magnetic material, and
each of the first and second plated holes comprise a first conductive portion, further comprising:
a second magnetic material between the third and fourth surfaces within the region;
third and fourth plated holes through the second magnetic material, wherein each of the third and fourth plated holes comprise a second conductive portion;
a third dielectric material between the third and fourth plated holes; and
an electrically conductive feature on the third surface contacting:
the first conductive portion of the first plated through hole, and
the second conductive portion of the third plated through hole.

13. The apparatus of claim 12, wherein the electrically conductive feature is a first electrically conductive feature, further comprising a second electrically conductive feature contacting:
the first conductive portion of the second plated through hole, and
the second conductive portion of the fourth plated through hole, wherein
the first electrically conductive feature and the second electrically conductive feature are substantially parallel in a plane parallel to the third surface.

14. The apparatus of claim 9, wherein the second dielectric material comprises a gas comprising oxygen and nitrogen.

15. The apparatus of claim 9, wherein each of the first and second plated holes comprise conductive portions and insulating material portions, and each conductive portion is between a corresponding insulating material portion and the magnetic material.

16. A system comprising:
a first die over a second die, the first die comprising a first surface, the second die comprising a second surface and a third surface opposite the second surface, wherein the first surface is facing the second surface;
a substrate under the second die, the substrate comprising:
a fourth surface facing the third surface;
interconnects between the third surface and the fourth surface to couple the substrate to the second die;
a layer comprising solid glass, a first side, and a second side opposite the first side;
a dielectric material over the layer and within an opening through the layer;
a continuous body of magnetic material within the dielectric material between the first and second sides; and
a first plated hole, a second plated hole, and a zone between the first and second plated holes, wherein the first and second plated holes extend through the magnetic material.

17. The system of claim 16, wherein the magnetic material is a first magnetic material and the zone is a first zone, further comprising:
a continuous body of second magnetic material within the dielectric material between the first and second sides;
a third plated hole, a fourth plated hole, and a second zone between the third and fourth plated holes, wherein the third and fourth plated holes extend through the second magnetic material; and
an electrically conductive feature extending between the first and third plated holes.

18. The system of claim 16, wherein the interconnects are first interconnects, further comprising second interconnects comprising hybrid bonds between the first surface and the second surface to couple the first die with the second die.

19. The system of claim 16, wherein the zone extends vertically between the first and second sides, and comprises a dielectric material different from the magnetic material.

20. The system of claim 16, further comprising a through-glass via extending through the layer and the dielectric material, wherein the layer comprises at least 23 percent silicon and at least 26 percent oxygen, by weight.
